(19) United States
(12) Patent Application Publication
(10) Pub. No.: US 2026/0150762 A1
(43) Pub. Date: May 28, 2026

(54) Stacking and Racking Semiconductor Chips Glass or Ceramic Circuits

(71) Applicant: Sciperio, Inc, Orlando, FL (US)

(72) Inventor: Kenneth H. Church, Orlando, FL (US)

(73) Assignee: Sciperio, Inc, Orlando, FL (US)

(21) Appl. No.: 19/399,252

(22) Filed: Nov. 24, 2025

Related U.S. Application Data
(60) Provisional application No. 63/726,117, filed on Nov. 27, 2024.

(51) Int. Cl. H01L 25/065; H01L 23/00; H01L 23/15; H01L 23/427; H01L 23/538

(52) U.S. Cl. CPC H10W 90/00; H10W 40/73; H10W 70/611; H10W 70/692; H10W 90/401; H10W 72/07331; H10W 72/325; H10W 72/351; H10W 90/22; H10W 90/288; H10W 90/734; H10W 90/735

(57) ABSTRACT

A microelectronics device includes a plurality of chips, a plurality of interconnect layers, each of the at least one interconnect layers comprised of one of glass and ceramic with circuitry patterned thereon. Each of the plurality of interconnect layers is operatively connected to neighboring ones of the plurality of chips and the plurality of interconnect layers using nanoparticle ink or paste to provide for electrical and mechanical bonding. At least one of the plurality of interconnect layers may have a surface extending across surfaces of multiple chips within the plurality of chips. The circuitry may include traces and vias to interconnect pads for I/O, ground, and power signals throughout the microelectronics device.

### RELATED APPLICATIONS

This application claims priority to U.S. Provisional Patent Application No. 63/726,117, filed Nov. 27, 2024, hereby incorporated by reference in its entirety.

### FIELD OF THE DISCLOSURE

The present disclosure relates to microelectronics packaging. More particularly, but not exclusively, the present disclosure relates to increasing density of microelectronics.

### BACKGROUND

In microelectronics, there are continuing demands for increased processing power, miniaturization, and higher integration density which have outpaced the capabilities of traditional semiconductor packaging techniques. Such demands may be associated with what is required to.

Conventional methods predominantly rely on planar stacking and wire bonding to interconnect chips, which inherently limits the three-dimensional (3D) integration potential of semiconductor devices. This two-dimensional approach restricts the number of chips that can be effectively stacked and interconnected, thereby constraining the functionality that can be achieved within a given volume.

Wire bonding, while reliable, introduces several limitations. It necessitates that chips be oriented in a specific manner—typically flat—due to the physical constraints of the bonding process. This orientation requirement prevents the utilization of alternative configurations, such as flipping chips on their sides (racking), which could otherwise significantly increase integration density. Moreover, wire bonds add parasitic inductance and capacitance to the circuits, adversely affecting signal integrity and limiting performance in high-speed or high-frequency applications.

Another significant challenge in microelectronics packaging is thermal management. As integration density increases, so does the heat generated by the densely packed components. Traditional packaging techniques often lack effective means to dissipate this heat, leading to overheating issues that can compromise device performance and reliability. The inability to incorporate efficient cooling solutions within the packaging exacerbates this problem, especially in applications requiring sustained high performance.

Furthermore, as semiconductor fabrication advances toward feature sizes of 1 micron and below, the precision required for aligning and connecting these tiny structures exceeds the capabilities of many existing packaging technologies. Traditional printed circuit boards (PCBs) and interconnect methods may not provide the necessary resolution or accuracy, leading to alignment errors and unreliable connections. Additionally, integrating passive components into the packaging typically involves separate manufacturing processes, increasing complexity and cost.

Additionally, as data rates increase in high-performance computing applications, electrical interconnects face fundamental limitations due to signal integrity issues, electromagnetic interference, and power consumption at high frequencies. Optical interconnects offer potential solutions to these challenges but have traditionally required separate optical layers or modules that add complexity and limit integration density. There exists a need for packaging solutions that can seamlessly integrate both electrical and optical signal routing within the same interconnect structure.

These challenges underscore the need for innovative packaging solutions that overcome the limitations of traditional methods. Advancements are required to enable versatile chip orientations, higher interconnect densities, efficient thermal management, and seamless integration of passive components—all at micron-scale precision. Overcoming such challenges would enable microelectronics packaging for high speed computing, supercomputing, data analytics, RF applications, next generation AR/VR, and AI amongst other applications.

### SUMMARY

Therefore, it is a primary object, feature, or advantage to improve over the state of the art.

It is a further object, feature, or advantage to provide for improved microelectronics packaging.

A still further object, feature, or advantage is to provide for more circuitry within a smaller volume.

A still further object, feature, or advantage is to shrink the overall size of 3D High Density circuits while shrinking overall size and increasing functionality.

It is a further object, feature, or advantage to enhance 3D stacking of semiconductor chips by integrating glass or ceramic circuits with conductive patterns and vias.

It is a still further object, feature, or advantage to allow chips to be oriented in various configurations—including stacking flat and flipping on their sides (“racking”)—while maintaining effective power, ground, and signal connections.

It is another object, feature, or advantage to replace traditional wire bonding techniques with glass or ceramic circuitry, enabling micron-scale interconnections and significantly increasing circuit density within a smaller volume.

Yet another object, feature, or advantage is to incorporate cooling solutions within the glass or ceramic layers—such as air gaps, cooling channels, or thermally conductive metal planes—to effectively manage heat in high-density, high-power circuits.

It is also an object, feature, or advantage to integrate passive components directly into the glass or ceramic circuits, enhancing functionality and simplifying the manufacturing process.

Another object, feature, or advantage is to utilize nano ink and nano paste to connect chip pads to glass or ceramic pads, ensuring precise alignment and strong electrical connections at the micron scale.

A further object, feature, or advantage is to achieve a volume compression of up to 50,000 times compared to current technologies, enabling the development of compact supercomputers and advanced AI systems.

An additional object, feature, or advantage is to apply lithographic techniques to pattern glass or ceramic circuits at scales of 1 micron or less, matching the density of semiconductor chips.

Yet a further object, feature, or advantage is to facilitate applications in microelectronic packaging, high-speed computing, data analytics, RF applications, and next-generation AR/VR devices by providing a method to route signals, power, and ground in highly dense configurations.

Yet another object, feature, or advantage is to integrate optical waveguides within the glass or ceramic interconnect layers to enable optical signal routing alongside electrical signal routing, providing a hybrid electrical-optical interconnect architecture that combines the benefits of both transmission methods on the same substrate.

According to another object, feature, or advantage, methods, devices and systems for designing and implementing a multi-layer conductive architecture that utilizes traces and vias to interconnect pads for I/O, ground, and power signals, similar to the methodology employed in printed circuit board fabrication, but using glass or ceramic layers along with chips.

One or more of these and/or other objects, features, or advantages will become apparent from the specification and claims that follow. No single embodiment needs to exhibit each and every object, feature, or advantage as different embodiments may have different objects, features, and advantages.

According to one aspect, a microelectronics device may include a plurality of chips and a plurality of interconnect layers, each of the at least one interconnect layers comprised of one of glass and ceramic with circuitry patterned thereon. The circuitry may include traces and vias to interconnect pads for I/O, ground, and power signals throughout the microelectronics device. Each of the plurality of interconnect layers may operatively connected to neighboring ones of the plurality of chips and the plurality of interconnect layers using nanoparticle ink or paste to provide for electrical and mechanical bonding. At least one of the plurality of interconnect layers may have a surface extending across surfaces of multiple chips within the plurality of chips. The surfaces of the multiple chips may include edge surfaces. At least a first subset of the plurality of chips and the plurality of interconnect layers may be arranged to form a stack. At least a second subset of the plurality of chips and the plurality of interconnect layers may be arranged to form a rack. The circuitry may be patterned on the interconnect layers includes vias, conductive patterns, and passive components. At least one of the plurality of interconnect layers may be spaced apart from a neighboring one of the plurality of chips and the plurality of interconnect layers to allow for cooling. A computing device may be formed from the microelectronics device.

According to another aspect a microelectronics device may include a plurality of chips, a plurality of interconnect layers, each of the at least one interconnect layers comprised of one of glass and ceramic with circuitry patterned thereon. The circuitry may include traces and vias to interconnect pads for I/O, ground, and power signals throughout the microelectronics device. The plurality of chips and the plurality of interconnect layers may have electrical and mechanical bonds therebetween formed with nanoparticle ink or paste. The plurality of chips and the plurality of interconnect layers may be arranged to enhance density of the microelectronics package through edge connections such that at least one of the plurality of interconnect layers has a surface extending across surfaces of multiple chips within the plurality of chips and/or multiple interconnect layers within the plurality of interconnect layers. The plurality of chips and the plurality of interconnect layers may be further arranged to provide at least one stack and at least one rack. The circuitry may be patterned on the interconnect layers includes vias, conductive patterns, and passive components. At least one of the plurality of interconnect layers may be spaced apart from a neighboring one of the plurality of chips and the plurality of interconnect layers to allow for cooling. Each of the plurality of chips may include a bare die. The circuitry may include conductive patterns forming pads. The circuitry may include a conductive plane to provide cooling.

According to another aspect, a method of manufacturing a microelectronics device includes arranging a plurality of chips and a plurality of interconnect layers, each of the at least one interconnect layers comprised of one of glass and ceramic with circuitry patterned thereon to provide power, ground and signal connections throughout the microelectronics device while using nanoparticle paste to electrically and mechanically bond neighboring ones of the plurality of chips and the plurality of interconnect layers. The arranging may include arranging the plurality of chips and the plurality of interconnect layers to form at least one stack and at least one rack. The arranging may further include controlling spacing between one or more of the interconnect layers and one or more of the plurality of chips to assist with cooling. At least one of the plurality of interconnect layers may have a surface extending across surfaces of multiple chips within the plurality of chips. The circuitry may be patterned on the interconnect layers includes vias, conductive patterns, and passive components. The method may further include incorporating thermal handling into the microelectronics device wherein the microelectronics device is configured to provide for thermal handling by at least one of (a) maintaining spacing between adjacent structures each of the adjacent structures being one of an interconnect layer and a chip, (b) including microchannels configured to allow air flow or fluid flow to pull heat out from the microelectronics device, (c) including conductive heat pipes to pull heat across a thermally conductive pattern in a layer and operatively coupled with vias for pulling heat between layers within the microelectronics device, (d) combinations thereof.

According to another aspect, a microelectronics device includes a plurality of chips, a plurality of interconnect layers, each comprised of glass or ceramic with both electrical circuitry and integrated optical waveguides patterned thereon, wherein the electrical circuitry comprises conductive traces and vias for electrical signal, power, and ground routing, wherein the integrated optical waveguides provide optical signal routing pathways, and wherein the electrical circuitry and integrated optical waveguides coexist on one or more of the interconnect layers to enable hybrid electrical-optical signal transmission. The integrated optical waveguides may be formed using at least one of ion exchange, sol-gel deposition, photolithography, or direct laser writing techniques.

### BRIEF DESCRIPTION OF THE DRAWINGS

FIG. 1 illustrates a chip and an interconnect layer in the form of glass circuitry.

FIG. 2 illustrates a chip and an interconnect layer in different orientations.

FIG. 3 illustrates a stack which includes a plurality of chips and a plurality of interconnect layers along with a rack with a plurality of chips and interconnect layers.

FIG. 4 illustrates a chip in a vertical orientation.

FIG. 5 illustrates a plurality of chips and a plurality of interconnect layers in a vertical orientation with varying spacing intervals therebetween.

FIG. 6 illustrates a plurality of stacks and racks including interconnect layers with circuitry thereon.

FIG. 7 illustrates a plurality of stacks and racks including an interconnect layer which extends between a stack and a rack.

FIG. 8 illustrates a device which is highly dense and includes a plurality of stacks and racks.

FIG. 9 is another example of racks and stacks in a device where an interconnect layer can span across both a rack and a stack.

FIG. 10 is another example of racks and stacks in a device where racks and stacks may have different dimensions.

### DETAILED DESCRIPTION

The present disclosure provides for enhancing 3D stacking of chips by adding glass circuitry that has conductive patterns on both sides connected using vias in the glass or a one sided conductive layout. The glass serves a similar purpose as layers inside a printed circuit board (PCB). A PCB can have two, three or even 50 layers of conductive patterns and vias. Active components are placed on top of complex PCBs and sometimes on the bottom as well.

According to the present disclosure, chips or active components (such as bare dies) can be placed in between the glass layers and continue to stack to allow a large number of chips to be connected together. The glass circuit may also have passive components which are made at the same time as the conductive patterns and vias. Thus, unlike stacking today which is limited to planar stacking, stacking may be performed in any number of ways. Flipping the chips on their edge, like a book, allows more functions but connecting these to the normal stacked chips is not possible with wire bonding or other conventional techniques. Using glass to replace wire bonding, any chips may be connected to any other chips in any other orientation. Cooling channels or spacing may also be provided to allow air to flow and cool high power or high density circuits that will get hot due to the increased density in a small volume.

Thus, it is significant that the present disclosure not only provides for flipping chips on their side in a stack and rack configuration but also provides power, ground and more signals in a small package. This may be implemented on the one micron scale (or smaller). For example, glass (or ceramic) may be patterned using lithographic approaches which can achieve 1 micron scale or smaller. Highly dense patterns on glass matching highly dense semiconductor chips provides a method to route signals, add power and ground. Moreover cooling may be added through spacing the glass or adding channels or metal cooling pipes (cooling pipes may include copper or gold planes that are thermally conductive and pull heat away from the chips).

The methods provide for fabricating glass or ceramic circuit patterns on one or two sides that can be used to connect and reroute active devices in stacks (chip stacking) and racks (chips on their sides like books on a bookshelf). 3D High Density circuits may be stacked on a circuit layout (silicon or glass) to shrink the overall size and increase the function. Using glass breakout patterns or circuits in between the stacks allows many more chips to be stacked and properly routed. Placing chips on their sides and connecting to chips that are stacked flat allow more circuitry in a smaller volume. The glass or ceramic circuits allow for many layers to be added in a complex and highly dense design.

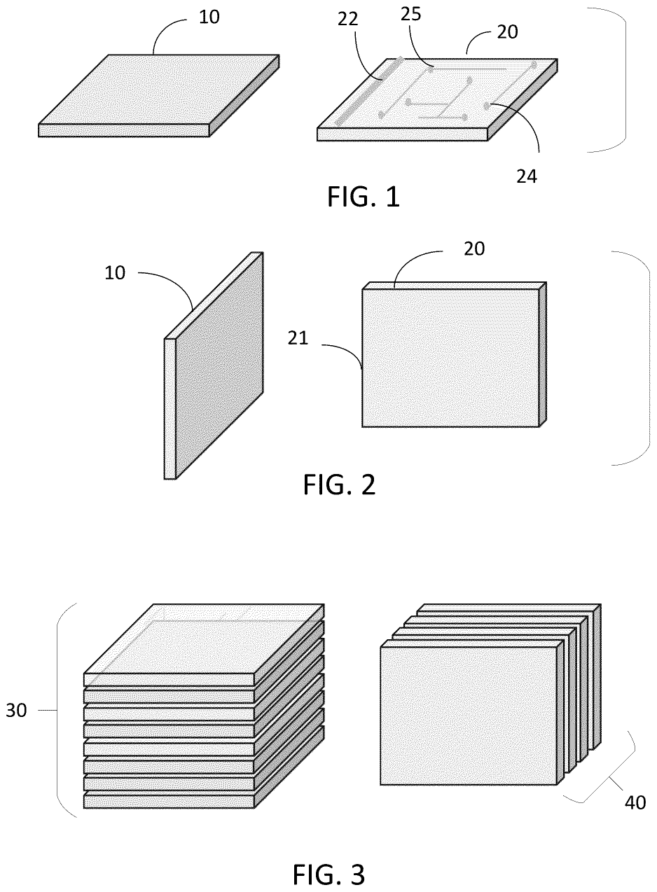

FIG. 1 illustrates a chip 10. The chip 10 may be a semiconductor device. Also shown in FIG. 1 is an interconnect layer 20 which is formed of glass or ceramic with circuitry disposed 22 thereon which may include one or more pads 24 and one or more vias 25. The interconnect layer 20 may, for example, be formed of glass and configured to provide power, ground, and signals through the use of highly dense patterns on the glass. Thus, the interconnect layer may include traces and vias to interconnect pads for I/O, ground, and power signals throughout the microelectronics device. Alternatively, the interconnect layer 20 may be formed from ceramic.

The interconnect layer 20 may form a layer within a stack or rack of chips and other interconnect layers 20. The interconnect layer 20 may also be connected to edges of a stack or rack of chips and other interconnect layers. The chip 10 may include metallized areas. These metallized areas may include pads or other areas. Although different types of metals may be used, one type of metal which may be used is gold to allow for excellent conductivity and without oxidizing or corroding over time and temperature. Elements or features such as precision microdispensed dots and line of conductive nano ink or nano paste may also be present.

The interconnect layer uses glass or ceramic substrates instead of traditional silicon, FR4, or ceramic substrates. Glass substrates are advantageous over silicon, FR4, and ceramic substrates in various ways which may be important to a particular application. For example, glass substrates may provide excellent thermal stability, electrical insulation, smooth surface, and the ability to be patterned with fine conductive features. The interconnect layers may each be a high quality glass or ceramic with a thickness from about a few hundred microns to about a millimeter.

The glass or ceramic substrate of the interconnect layer may be patterned with the elements or features such as with conductive lines, vias, and passive components such as resistors, capacitors, and inductors. Methods such as photolithography, etching, or other suitable microfabrication techniques may be used.

Conductive lines and vias or other features may be formed from highly conductive metals such as copper, gold, or silver. Pads are also formed. Pads are positioned to align precisely with pads on other chips or interconnect layers during stacking. The passive components may be integrated through additional patterning processes.

In addition to electrical conductive patterns, the interconnect layer 20 may include integrated optical waveguides formed within or on the glass or ceramic substrate. These optical waveguides enable optical signal routing alongside traditional electrical signal routing through conductive traces. The optical waveguides can be configured to route high-bandwidth optical signals between chips while the conductive traces handle power, ground, and lower-speed electrical signals on the same interconnect layer. This hybrid approach leverages the advantages of both electrical and optical signal transmission, with optical waveguides providing high-speed, low-latency data transmission with minimal electromagnetic interference, while electrical traces efficiently distribute power and ground connections.

The coexistence of electrical and optical signal routing pathways on a single glass or ceramic substrate provides significant advantages for high-performance computing applications. Optical waveguides can transmit data at higher bandwidths with lower power consumption compared to electrical interconnects, particularly over longer distances within the microelectronics package. The glass substrate is particularly well-suited for optical waveguide integration due to its optical transparency and compatibility with standard waveguide fabrication processes. Chips may include both electrical pads for connection to conductive traces and optical interfaces (such as vertical cavity surface-emitting lasers (VCSELs) or photodetectors) for coupling to the integrated waveguides. The nanoparticle paste provides mechanical bonding while maintaining precise alignment between optical components on the chips and the waveguides in the interconnect layers.

FIG. 2 illustrates the chip 10 and the interconnect layer 20. The chip 10 and the interconnect layer 20 are positioned generally orthogonal to one another so that an edge surface 21 of the interconnect layer 20 is directed towards a top or bottom planar surface (one of the sides with greatest surface area) of the chip 10.

FIG. 3 illustrates a stack 30. The stack 30 includes both a plurality of chips 10 as well as a plurality of interconnect layers 20. Note that in the stack 30, the larger planar surface of a chip (its top or bottom) may be in contact with a planar surface (top or bottom) of either another chip or an interconnect layer. Also shown in FIG. 3 is a rack 40. A rack 40 is a stack which has been rotated relative to another stack 30. The rack 40 may be connected to the stack 30 such that edges of the rack come into contact with edges of the stack. It is to be understood, that although as shown here, racks and stacks show a 90 degree rotation, any number of other rotations may be used. It is to be further understood that although the stacks or racks shown are cuboid (which also may be referred to as rectangular prism or rectangular parallel piped) other geometries may be used including pyramidal stacks, dodecagonal (12-sided) prism stacks, or any number of other geometries. Other geometries may be useful to provide different thermal distributions, improved signal paths, or to allow for different edge effects as may be appropriate in a particular design or application. Moreover, different geometries may be integrated into a single design.

The present disclosure provides a method for fabricating a microelectronic package using glass or ceramic interconnect layers along with chips or other layers. A conductive nanoparticle paste is applied to adhere neighboring layers. This allows for layers to be stacked to form the stack 30 or rack 40. This method of bonding adjacent layers also enables electrical and mechanical bonding not just to a layer within a stack or rack but also along edges of a stack or rack. The conductive nanoparticle paste may be sintered to provide both electrical and mechanical bonding between an interconnect layer and edges of a rack or stack.

Each chip or interconnect layer may contain conductive pads, lines, vias, and passive components formed with nano ink or nanoparticle paste. The nanoparticle paste used may have a viscosity of at least 5,000 cP, typically within a range of 5,000 cP to 5,000,000 cP. In some embodiments, the nanoparticle paste may have a viscosity of at least 10,000 cP, typically within a range of 10,000 cP to 1,000,000 cP. The stacking (or racking) process allows for precise alignment of the chips and interconnect layers. Additional chips can be added to the stack, with the nanoparticle paste applied to the surfaces to be bonded, and the process of stacking and sintering repeated. When using silver nanoparticles in the nanopaste, heating the stack sinters the silver, forming a pure silver interface.

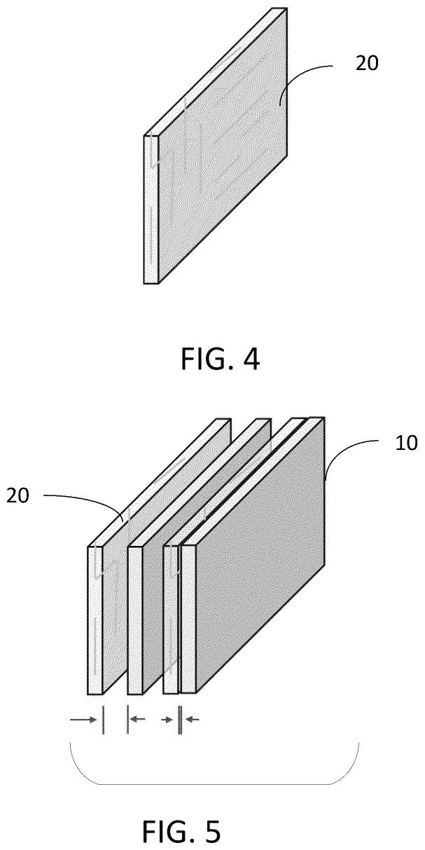

FIG. 4 illustrates the interconnect layer 20 in a vertical position.

FIG. 5 illustrates another plurality of chips 10 and interconnect layers 20. Immediately adjacent chips 10 and interconnect layers 20 may have different spacing therebetween. Spacing the interconnect layers 20 is one way of adding cooling. Thus, increasing the spacing allows for air to flow and for added cooling of high power or high density circuits which may otherwise get too hot due to the increased density within a small volume. Spacing may be controlled in various ways. For example, laser-micromachining may be employed to create pits, which are then filled with glass or ceramic beads to control separation thickness. Nanoparticle paste may be applied to both metallized and non-metallized areas to assist in bonding and maintaining separation between substrates. The stacking or racking may be performed using a pick and place machine, which applies heat and pressure, ensuring precise alignment and bonding. Spacing may also be achieved using spaces in the form of glass or ceramic beads or microdispensed and sintered nano paste.

It should be understood that although spacing may be controlled in order to manage heat, it is not the only method for doing so. In the same way signals through conductive traces may be routed, heat may be routed or moved using (1) the spaces between glass and chips or spaces between glass and glass or spaces between chips and chips, (2) microchannels that allow air flow or fluid flow to pull heat out, 3) copper heat pipes, which will be flat and large surface area to pull heat across the thermally electrically and thermally conductive patterns and this coupled with vias to pull heat from layer to layer and finally 4) a combination of any or all these.

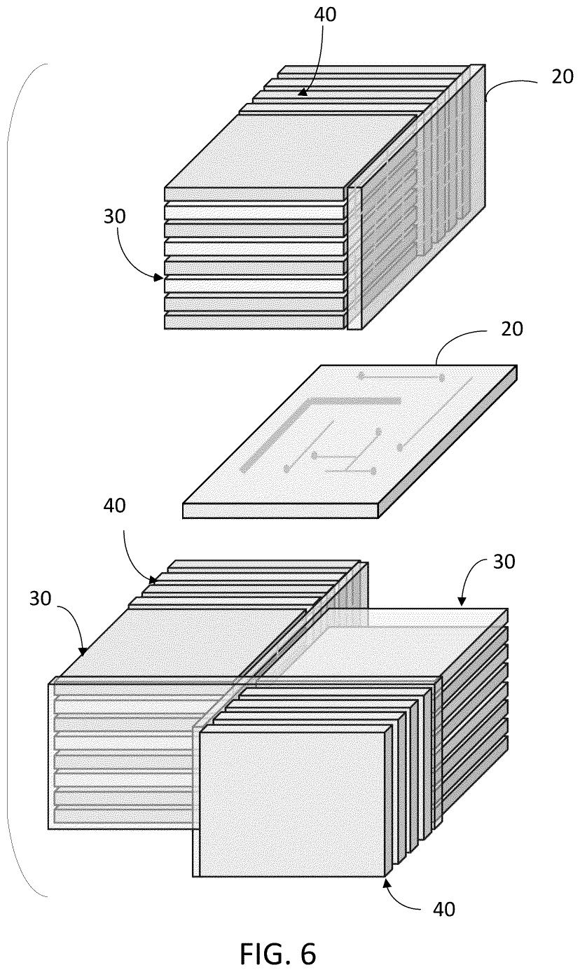

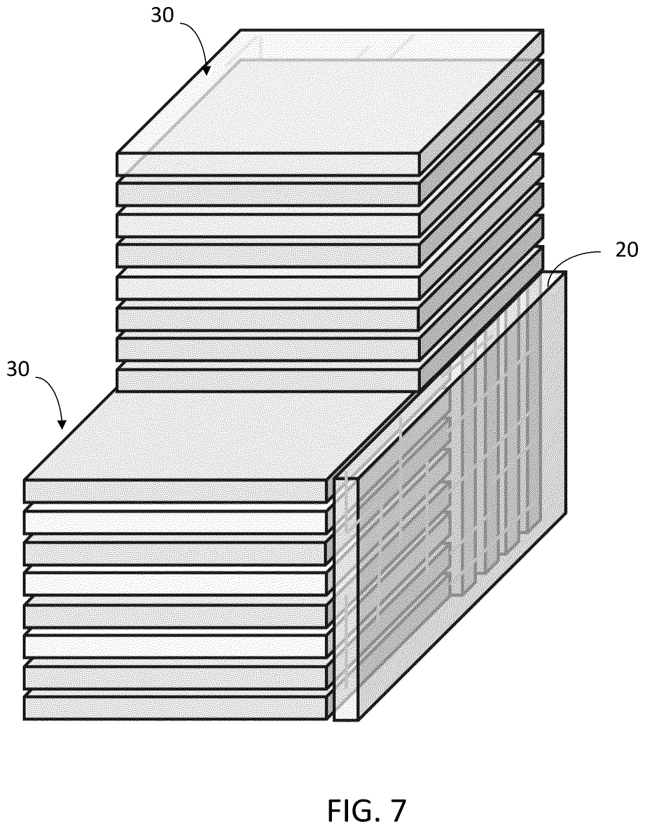

FIG. 6 illustrates another example of microelectronics packaging which incorporates multiple stacks 30, multipole racks 40 formed from chips and interconnect layers along with additional interconnect layers 20 between stacks, between racks, or between stacks and racks. As should be apparent from FIG. 6 high density circuits can be made from combining these various components. Moreover, the use of interconnect layers 20 along edges of stacks or racks allow for routing of connections formed by nano ink or nano paste between different chips within in different stacks or racks.

FIG. 7 further illustrates combining multiple stacks 30, racks and using an interconnect layer 20.

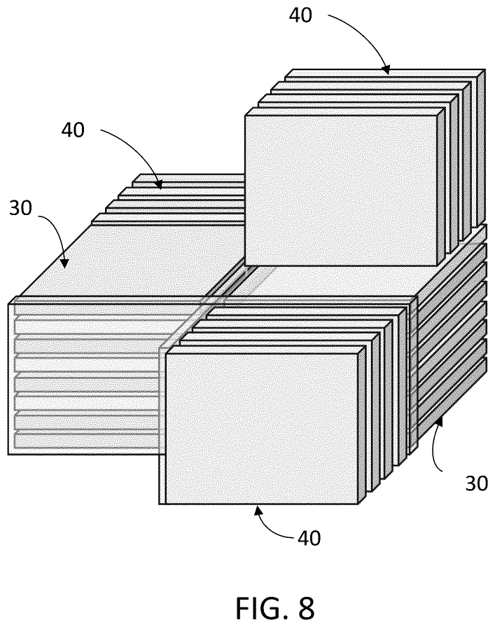

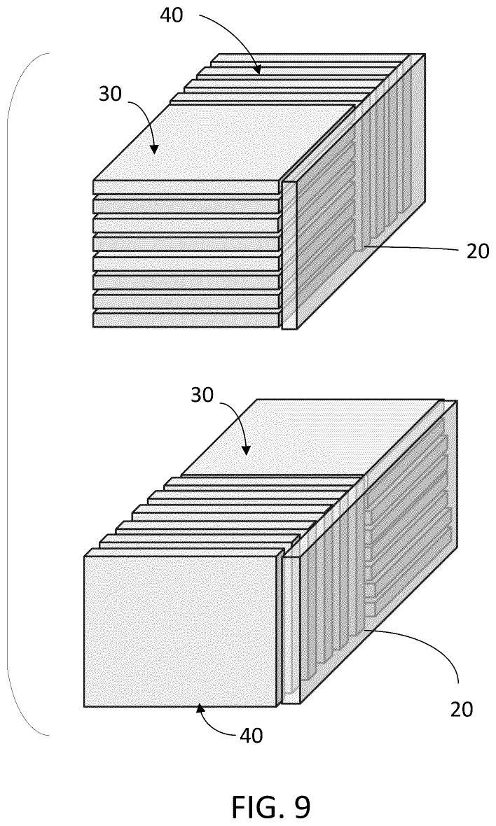

FIG. 8 illustrates a further example of combining multiple stacks and racks.

FIG. 9 illustrates yet another example of combining multiple stacks and racks where an insulating substrate connects both edges of a rack 40 and a stack 30. It is to be understood that any number of geometric configurations may be formed by stacks and racks or other components including non-uniform or heterogenous 3D structures. For example, the resulting structures may be sparse 3D structures with lower volumetric density than cubic packing which may be formed with variable interconnecting lengths, void spaces, or channels, and branching or dendritic patterns, variable heights, etc. Such flexibility in addition to providing desired density allows for non-uniform thermal paths, complex signal routing, fault tolerance or redundancy with multiple potential interconnect paths, or other advantages as may be appropriate in a particular design or application.

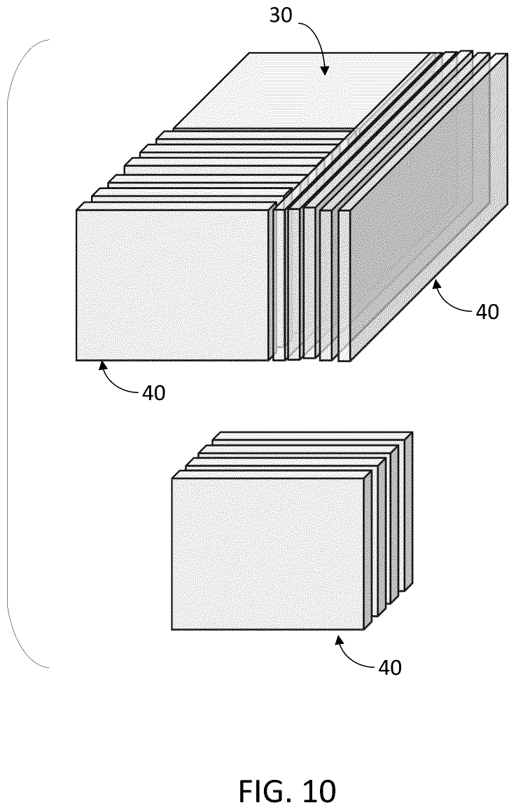

FIG. 10 illustrates a further example where one of the racks is of a different length and orientation than another rack.

It should be understood that the present disclosure provides methods and systems with far-reaching implications. There is significant commercial value in providing increased density of circuitry in a smaller volume while also handling the heat. It is estimated that with this technique and using glass to provide power, ground and signal, the volume compression over the state of the art is more than 50,000 times reduction. Even a fraction of that estimate is a significant increase.

Aside from that understanding, specific applications will be enabled and enhanced by the present disclosure. For example, next generation AI requires tremendous data and signal processing which takes physically large computers. This approach will take those and shrink to small cubes that will have more processing power than today's state of the art while also reducing power requirements.

Throughout this detailed description, the use of relative terms such as “first,” “second,” “top,” “bottom,” “upper,” “lower,” “above,” “below,” “horizontal,” “vertical,” “inner,” “outer,” “front,” and “back” are for convenience and descriptive purposes only. These terms should not be construed as limiting the scope of the invention or excluding alternative configurations, orientations, or relative relationships between the described elements. The relative positions and orientations are used to facilitate the description of the present invention and can vary depending on the specific application or environment in which the invention is utilized.

Similarly, references to directions such as “X,” “Y,” and “Z” are intended to describe spatial orientations relative to each other and are not to be interpreted as restrictive or limiting. The invention can be practiced in various orientations and spatial arrangements without departing from the spirit and scope of the disclosed embodiments.

Similarly, references to paste and does not preclude it from being anything except a higher viscosity than standard inks. Clay, putty, or other viscous material terminologies may be considered in the fabrication process.

Any relative terminology used herein is for explanatory purposes and should not be interpreted as restrictive. The invention encompasses various modifications, alternative configurations, and variations that fall within the scope of the appended claims and their equivalents.

Although specific embodiments and features have been shown and described, it is to be understood that any number of combinations, options, and variations are contemplated including variations in the nanoparticle paste including type of nanoparticles and size of nanoparticles, the viscosity of the nanoparticle paste and other options. Unless specifically claimed, the type of materials used, including the type of substrate, the type of material used in creating vias, the type of material used on the edges, the number of layers within a stack or rack, the geometric configuration of stacks, racks, or combinations thereof, and other variations, options, and alternatives.

What is claimed is:

1. A microelectronics device, comprising:
a plurality of chips;
a plurality of interconnect layers, each of the at least one interconnect layers comprised of one of glass and ceramic with circuitry patterned thereon;
wherein the circuitry comprises traces and vias to interconnect pads for I/O, ground, and power signals throughout the microelectronics device;
wherein each of the plurality of interconnect layers is operatively connected to neighboring ones of the plurality of chips and the plurality of interconnect layers using nanoparticle ink or paste to provide for electrical and mechanical bonding.

2. The microelectronics device of claim 1 wherein at least one of the plurality of interconnect layers has a surface extending across surfaces of multiple chips within the plurality of chips.

3. The microelectronics device of claim 2 wherein the surfaces of the multiple chips include edge surfaces.

4. The microelectronics device of claim 1 wherein at least a first subset of the plurality of chips and the plurality of interconnect layers are arranged to form a stack.

5. The microelectronics device of claim 4 wherein at least a second subset of the plurality of chips and the plurality of interconnect layers are arranged to form a rack.

6. The microelectronics device of claim 1 wherein the microelectronics device is configured to provide for thermal handling by at least one of (a) maintaining spacing between adjacent structures each of the adjacent structures being one of an interconnect layer and a chip, (b) including microchannels configured to allow air flow or fluid flow to pull heat out from the microelectronics device, (c) including conductive heat pipes to pull heat across a thermally conductive pattern in a layer and operatively coupled with vias for pulling heat between layers within the microelectronics device, (d) combinations thereof.

7. The microelectronics device of claim 1 wherein at least one of the plurality of interconnect layers is spaced apart from a neighboring one of the plurality of chips and the plurality of interconnect layers to allow for cooling.

8. The microelectronics device of claim 1 wherein at least one of the plurality of interconnect layers further comprises integrated optical waveguides patterned within or on the glass or ceramic substrate for optical signal routing.

9. A computing device comprising the microelectronics device of claim 1.

10. A microelectronics device, comprising:
a plurality of chips;
a plurality of interconnect layers, each of the at least one interconnect layers comprised of one of glass and ceramic with circuitry patterned thereon;
wherein the circuitry comprises traces and vias to interconnect pads for I/O, ground, and power signals throughout the microelectronics device;
wherein the plurality of chips and the plurality of interconnect layers have electrical and mechanical bonds therebetween formed with nanoparticle ink or paste;
wherein the plurality of chips and the plurality of interconnect layers are arranged to enhance density of the microelectronics package through edge connections such that at least one of the plurality of interconnect layers has a surface extending across surfaces of multiple chips within the plurality of chips and/or multiple interconnect layers within the plurality of interconnect layers.

11. The microelectronics device of claim 10 wherein the plurality of chips and the plurality of interconnect layers are further arranged to provide at least one stack and at least one rack.

12. The microelectronics device of claim 10 wherein at least one of the plurality of interconnect layers is spaced apart from a neighboring one of the plurality of chips and the plurality of interconnect layers to allow for cooling.

13. The microelectronics device of claim 10 wherein each of the plurality of chips comprises a bare die.

14. The microelectronics device of claim 10 wherein the microelectronics device is configured to provide for thermal handling by at least one of (a) maintaining spacing between adjacent structures each of the adjacent structures being one of an interconnect layer and a chip, (b) including microchannels configured to allow air flow or fluid flow to pull heat out from the microelectronics device, (c) including conductive heat pipes to pull heat across a thermally conductive pattern in a layer and operatively coupled with vias for pulling heat between layers within the microelectronics device, (d) combinations thereof.

15. The microelectronics device of claim 10 wherein the circuitry comprises a thermally conductive plane to provide for cooling.

16. A method of manufacturing a microelectronics device, comprising:
arranging a plurality of chips and a plurality of interconnect layers, each of the at least one interconnect layers comprised of one of glass and ceramic with circuitry patterned thereon to provide power, ground and signal connections throughout the microelectronics device while using nanoparticle ink or paste to electrically and mechanically bond neighboring ones of the plurality of chips and the plurality of interconnect layers.

17. The method of claim 16 wherein the arranging includes arranging the plurality of chips and the plurality of interconnect layers to form at least one stack and at least one rack.

18. The method of claim 17 wherein the arranging comprises controlling spacing between one or more of the interconnect layers and one or more of the plurality of chips to assist with cooling.

19. The method of claim 17 wherein at least one of the plurality of interconnect layers has a surface extending across surfaces of multiple chips within the plurality of chips.

20. The method of claim 17 wherein the circuitry patterned on the interconnect layers includes vias, conductive patterns, and passive components.

21. The method of claim 17 further comprising incorporating thermal handling into the microelectronics device wherein the microelectronics device is configured to provide for thermal handling by at least one of (a) maintaining spacing between adjacent structures each of the adjacent structures being one of an interconnect layer and a chip, (b) including microchannels configured to allow air flow or fluid flow to pull heat out from the microelectronics device, (c) including conductive heat pipes to pull heat across a thermally conductive pattern in a layer and operatively coupled with vias for pulling heat between layers within the microelectronics device, (d) combinations thereof.
